(19) United States
(12) Patent Application Publication
(10) Pub. No.: US 2026/0184921 A1
(43) Pub. Date: Jul. 2, 2026

(54) RESIN COMPOSITION, PREPREG, LAMINATED PLATE, PRINTED WIRING BOARD, AND SEMICONDUCTOR PACKAGE

(71) Applicant: Resonac Corporation, Minato-ku, Tokyo (JP)

(72) Inventors: Shiori MATSUOKA, Minato-ku, Tokyo (JP); Yukio NAKAMURA, Minato-ku, Tokyo (JP); Makoto YANAGIDA, Minato-ku, Tokyo (JP); Fumitaka UENO, Minato-ku, Tokyo (JP)

(21) Appl. No.: 18/855,710

(22) PCT Filed: Oct. 11, 2023
(86) PCT No.: PCT/JP2023/036836

§ 371 Date: Oct. 10, 2024

(30) Foreign Application Priority Data
Oct. 19, 2022 (JP) 2022-167373

(51) Int. Cl. C08L 79/08; C08F 299/02; C08J 5/24; C08K 3/36; C08K 5/14; C08K 5/3445; C08K 5/521; C08K 7/18; H05K 1/03

(52) U.S. Cl. CPC C08L 79/085; C08F 299/022; C08J 5/244; C08K 3/36; C08K 5/14; C08K 5/3445; C08K 5/521; C08K 7/18; H05K 1/0326; C08J 2353/00; C08K 2201/005; C08L 2203/16; C08L 2203/20; C08L 2205/035; H05K 2201/0129

(57) ABSTRACT

The present invention relates to a resin composition containing (A) one or more selected from the group consisting of maleimide resins having one or more N-substituted maleimide groups, and derivatives of the maleimide resins and (B) a phosphate ester compound containing two or more phosphorus atoms, in which the group connecting at least two phosphorus atoms contains two or more aromatic rings, a prepreg, a laminated plate, a resin film, a printed wiring board and a semiconductor package, using the resin composition.

### TECHNICAL FIELD

The present embodiment relates to a resin composition, prepreg, a laminated plate, a printed wiring board, and a semiconductor package.

### BACKGROUND ART

In recent years, there has been an increasing demand for downsizing and weight reduction, increasing density of wiring, increasing calculation processing speed, etc., for the printed wiring board which is used in electronic devices, communication devices, etc. Accordingly, higher reliability than before has been demanded for insulating layers of printed wiring boards.

Conventionally, thermosetting resins have been used as insulating materials for printed wiring boards.

Epoxy resins, which has excellent balance of insulation properties, heat resistance, cost, etc., have been common as thermosetting resins used for insulating materials, however, it is becoming increasingly difficult for epoxy resins to satisfy the required level of performance in recent years in terms of heat resistance.

Therefore, as a thermosetting resin which is more excellent in heat resistance, maleimide resins are used as insulating materials for printed wiring boards (for example, Patent Literature 1, etc.).

### CITATION LIST

### Patent Literature

PTL 1: JP-A-2022-013142

### SUMMARY OF INVENTION

### Technical Problem

As described above, the development of fine wiring in electronic devices, etc., has been remarkable, and when the melt viscosity of the insulating material used for embedding fine wiring patterns is high, voids and the like may occur in the insulating layer. Maleimide resins are excellent in heat resistance and conductor adhesion properties, however tend to have a high lowest melt viscosity, therefore, it is desirable to reduce the melt viscosity of insulating materials while taking advantage of the characteristics of maleimide resins.

In view of such a current situation, an object of the present embodiment is to provide a resin composition which has a low lowest melt viscosity while using a maleimide resin as a thermosetting resin, and a prepreg, a laminated plate, a resin film, a printed wiring board, and a semiconductor package using the resin composition.

### Solution to Problem

That is, the present embodiment provides the following [1] to [11].
[1] A resin composition containing:
(A) one or more selected from the group consisting of maleimide resins having a group containing a fused ring of an aromatic ring and an aliphatic ring and two or more N-substituted maleimide groups, and derivatives of the maleimide resins; and
(B) a phosphate ester compound containing two or more phosphorus atoms, in which the group connecting at least two phosphorus atoms contains two or more aromatic rings.
[2] The resin composition according to the above item [1], in which the group containing a fused ring of an aromatic ring and an aliphatic ring contained in the component (A) is a group containing an indane ring as the fused ring.
[3] The resin composition according to the above item [2],
in which the group containing an indane ring is a divalent group represented by the following general formula (A-1),

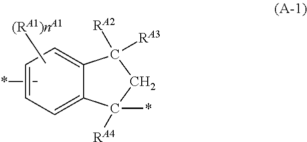

in which, R^{A1} is an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a hydroxy group, or a mercapto group; n^{A1} is an integer of 0 to 3; R^{A2} to R^{A4} are each independently alkyl groups having 1 to 10 carbon atoms; and* denotes a binding site.
[4] The resin composition according to any one of the above items [1] to [3],
in which the component (B) is a compound represented by the following general formula (B-1),

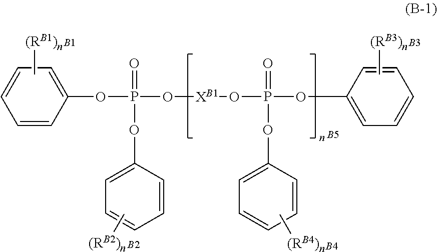

in which, R^{B1} to R^{B4} are each independently an aliphatic hydrocarbon group having 1 to 5 carbon atoms or a halogen atom; X^{B1} is a divalent group containing two or more aromatic rings; n^{B1} to n^{B4} are each independently an integer of 0 to 5; and n^{B5} is an integer of 1 to 5.
[5] The resin composition according to any one of the above items [1] to [4],
in which a content of the component (B) is 0.1 to 10 parts by mass with respect to the total amount (100 parts by mass) of the resin components in the resin composition.
[6] The resin composition according to any one of the above items [1] to [5], further containing:
(C) a compound having two or more functional groups containing an ethylenically unsaturated bond.
[7] A prepreg containing the resin composition according to any one of the above items [1] to [6] or a semi-cured product of the resin composition.
[8] A laminated plate including: a cured product of the resin composition according to any one of the above items [1] to [6]; and a metal foil.
[9] A resin film containing the resin composition according to any one of the above items [1] to [6] or a semi-cured product of the resin composition.
[10] A printed wiring board including a cured product of the resin composition according to any one of the above items [1] to [6].
[11] A semiconductor package including: the printed wiring board according to the above item [10]; and a semiconductor element.

### Advantageous Effects of Invention

According to the present embodiment, a resin composition which has a low lowest melt viscosity while using a maleimide resin as a thermosetting resin, and a prepreg, a laminated plate, a resin film, a printed wiring board, and a semiconductor package using the resin composition, can be provided.

### DESCRIPTION OF EMBODIMENTS

In the present description herein, a numerical range indicated by using “to” indicates a range including numerical values described before and after “to” as a minimum value and a maximum value, respectively.

For example, the expression of a numerical range “X to Y” (X and Y are real numbers) means a numerical range that is X or more and Y or less. Further, the expression of “X or more” in the description herein means X and a numerical value exceeding X. Furthermore, the expression of “Y or less” in the description herein means Y and a numerical value less than Y.

The lower limit value and the upper limit value of a numerical range described in the description herein can be arbitrarily combined with the lower limit value or the upper limit value of another numerical range, respectively.

In a numerical range described in the present description herein, the lower limit value or the upper limit value of the numerical range may be replaced with a value shown in Examples.

Each component and material exemplified in the present description herein may be used alone or may be used in combination of two or more kinds thereof, unless particularly otherwise specified.

In the present description herein, when a plurality of substances corresponding to each component are present in a resin composition, the content of each component in the resin composition means the total amount of the plurality of substances present in the resin composition, unless particularly otherwise specified.

In the description herein, the term “solid content” means a component other than a solvent, and includes a liquid state, a starch syrup state, and a wax state at room temperature. In the description herein, room temperature means 25° C.

The number-average molecular weight (Mn) and the weight-average molecular weight (Mw) in the description herein mean values measured by gel permeation chromatography (GPC) in terms of polystyrene. Specifically, the number-average molecular weight (Mn) and the weight-average molecular weight (Mw) in the present description herein can be measured by the method described in Examples.

The “semi-cured product” in the present description herein is synonymous with the resin composition in the B-stage state in JIS K6800 (1985), and the “cured product” is synonymous with the resin composition in the C-stage state in JIS-K6800 (1985).

The mechanism of action described in the present description herein is a guess, and does not limit the mechanism of achieving the effect of the present embodiment.

Aspects in which the matters described in the present description herein are arbitrarily combined are also included in the present embodiment.

### [Resin Composition]

A resin composition of the present embodiment is a resin composition containing:
(A) one or more selected from the group consisting of maleimide resins having a group containing a fused ring of an aromatic ring and an aliphatic ring and two or more N-substituted maleimide groups, and derivatives of the maleimide resins; and
(B) a phosphate ester compound (hereinafter, also referred to as “phosphate ester compound (B)”) containing two or more phosphorus atoms, in which the group connecting at least two phosphorus atoms contains two or more aromatic rings.

In the present description herein, each component may be sometimes referred to as an abbreviation such as the component (A), the component (B), which will be true for the other components as well in some cases.

The components which may be contained in the resin composition of the present embodiment will be explained in order below.

### <Component (A)>

The component (A) is one or more selected from the group consisting of maleimide resins having a group containing a fused ring of an aromatic ring and an aliphatic ring and two or more N-substituted maleimide groups, and derivatives of the maleimide resins.

The component (A) may be used alone or may be used in combination of two or more kinds thereof.

From the viewpoint of dielectric characteristic, conductor adhesion, and heat resistance, the component (A) is preferably an aromatic maleimide resin having a group containing a fused ring of an aromatic ring and an aliphatic ring and two or more N-substituted maleimide groups directly bonded to the aromatic ring, and more preferably an aromatic bismaleimide resin having a group containing a fused ring of an aromatic ring and an aliphatic ring, and two N-substituted maleimide groups directly bonded to the aromatic ring.

From the viewpoint of dielectric characteristic, conductor adhesion, and ease of production, the group containing a fused ring of an aromatic ring and an aliphatic ring contained in the component (A) is preferably a group containing a fused bicyclic structure as the fused ring, more preferably a group containing a fused ring of a benzene ring and an aliphatic ring, and still more preferably a group containing an indane ring. That is, the component (A) is preferably a maleimide resin having a group containing an indane ring and two or more N-substituted maleimide groups.

The group containing an indane ring is preferably a divalent group represented by the following general formula (A-1).

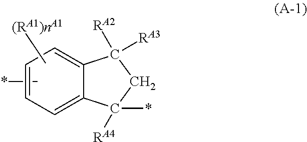

(In the formula, R^{A1} is an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a hydroxy group, or a mercapto group; n^{A1} is an integer of 0 to 3; R^{A2} to R^{A4} are each independently alkyl groups having 1 to 10 carbon atoms; and* denotes a binding site).

Examples of the alkyl group having 1 to 10 carbon atoms represented by R^{A1} in the general formula (A-1) include a methyl group, an ethyl group, a propyl group, a butyl group, a pentyl group, a hexyl group, a heptyl group, an octyl group, a nonyl group, and a decyl group. These alkyl groups may be either linear or branched.

Examples of the alkyl groups contained in the alkyloxy group having 1 to 10 carbon atoms and the alkylthio group having 1 to 10 carbon atoms represented by R^{A1} include the same alkyl groups having 1 to 10 carbon atoms as those described above.

Examples of the aryl group having 6 to 10 carbon atoms represented by R^{A1} include a phenyl group and a naphthyl group.

Examples of the aryl groups contained in the aryloxy group having 6 to 10 carbon atoms and the arylthio group having 6 to 10 carbon atoms represented by R^{A1} include the same aryl groups having 6 to 10 carbon atoms as those described above.

Examples of the cycloalkyl group having 3 to 10 carbon atoms represented by R^{A1} include a cyclopropyl group, a cyclobutyl group, a cyclopentyl group, a cyclohexyl group, a cycloheptyl group, a cyclooctyl group, a cyclononyl group, and a cyclodecyl group.

In a case where n^{A1} in the general formula (A-1) is an integer of 1 to 3, from the viewpoint of solvent solubility and reactivity, R^{A1} is preferably an alkyl group having 1 to 4 carbon atoms, a cycloalkyl group having 3 to 6 carbon atoms, or an aryl group having 6 to 10 carbon atoms, and more preferably an alkyl group having 1 to 4 carbon atoms.

Examples of the alkyl group having 1 to 10 carbon atoms represented by R^{A2} to R^{A4} include a methyl group, an ethyl group, a propyl group, a butyl group, a pentyl group, a hexyl group, a heptyl group, an octyl group, a nonyl group, and a decyl group. These alkyl groups may be either linear or branched. Among these, R^{A2} to R^{A4} are preferably an alkyl group having 1 to 4 carbon atoms, more preferably a methyl group or an ethyl group, and still more preferably a methyl group.

In the general formula (A-1), n^{A1} is an integer of 0 to 3, and when n^{A1} is 2 or 3, a plurality of R^{A1}'s may be the same as or different from each other.

Among the above, from the viewpoint of ease of production, the divalent group represented by the above general formula (A-1) is preferably a divalent group represented by the following general formula (A-1a) in which n^{A1} is 0, R^{A2} to R^{A4} are methyl groups, and more preferably a divalent group represented by the following general formula (A-1a′) or a divalent group represented by the following general formula (A-1a″).

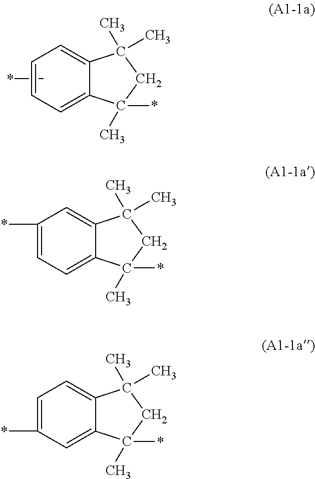

(In the formulas, * denotes a binding site).

The component (A) containing a divalent group represented by the general formula (A-1) is preferably one represented by the following general formula (A-2) from the viewpoints of dielectric characteristic, conductor adhesion, heat resistance, and ease of production.

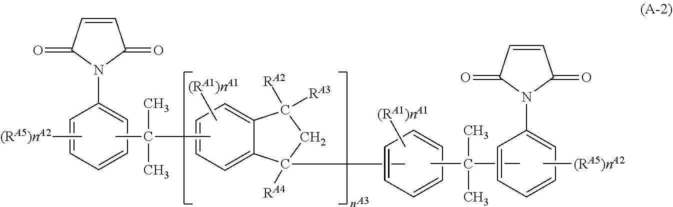

(In the formula, R^{A1} to R^{A4} and n^{A1} are the same as in the above general formula (A-1). R^{A5} is an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a nitro group, a hydroxy group, or a mercapto group, n^{A2} is each independently an integer from 0 to 4, and n^{A3} is a number from 0.95 to 10.0.)

In the general formula (A-2), a plurality of R^{A1}'s, a plurality of n^{A1}'s, a plurality of n^{A5}'s, and a plurality of n^{A2}'s may be the same as or different from each other.

In a case where n^{A3} is greater than 1, a plurality of R^{A2}'s, a plurality of R^{A3}'s, and a plurality of R^{A4}'s may be the same as or different from each other.

Examples of the alkyl group having 1 to 10 carbon atoms represented by R^{A5} in the general formula (A-2) include a methyl group, an ethyl group, a propyl group, a butyl group, a pentyl group, a hexyl group, a heptyl group, an octyl group, a nonyl group, and a decyl group. These alkyl groups may be either linear or branched.

Examples of the alkyl groups contained in the alkyloxy group having 1 to 10 carbon atoms and the alkylthio group having 1 to 10 carbon atoms represented by R^{A5} include the same alkyl groups having 1 to 10 carbon atoms as those described above.

Examples of the aryl group having 6 to 10 carbon atoms represented by R^{A5} include a phenyl group and a naphthyl group.

Examples of the aryl groups contained in the aryloxy group having 6 to 10 carbon atoms and the arylthio group having 6 to 10 carbon atoms represented by R^{A5} include the same aryl groups having 6 to 10 carbon atoms as those described above.

Examples of the cycloalkyl group having 3 to 10 carbon atoms represented by R^{A5} include a cyclopropyl group, a cyclobutyl group, a cyclopentyl group, a cyclohexyl group, a cycloheptyl group, a cyclooctyl group, a cyclononyl group, and a cyclodecyl group.

Among these, from the viewpoint of solvent solubility and ease of production, R^{A5} is preferably an alkyl group having 1 to 4 carbon atoms, a cycloalkyl group having 3 to 6 carbon atoms, and an aryl group having 6 to 10 carbon atoms, more preferably an alkyl group having 1 to 3 carbon atoms, and still more preferably a methyl group.

In the general formula (A-2), n^{A2} is an integer of 0 to 4, and from the viewpoint of compatibility with other resins, dielectric characteristics, conductor adhesion, and ease of production, n^{A2} is preferably an integer of 1 to 3, more preferably 2 or 3, and still more preferably 2.

When n^{A2} is one or more, the benzene ring and the N-substituted maleimide group have a twisted conformation, and the intermolecular stacking is suppressed, and thus the solvent solubility tends to be further improved. From the viewpoint of suppressing intermolecular stacking, when n^{A2} is 1 or more, the substitution position of R^{A5} is preferably an ortho-position with respect to the substitution position of N-substituted maleimide group.

From the viewpoint of dielectric characteristic, conductor adhesion, solvent solubility, handling ability, and heat resistance, n^{A3} in the general formula (A-2) is preferably a number of 0.98 to 8.0, more preferably a number of 1.0 to 7.0, and still more preferably a number of 1.1 to 6.0. Note that n^{A3} represents the average value of the number of structures containing an indane ring.

The component (A) represented by the general formula (A-2) is more preferably one represented by the following general formula (A-3), or one represented by the following general formula (A-4), from the viewpoints of dielectric characteristic, conductor adhesion, solvent solubility, and ease of production.

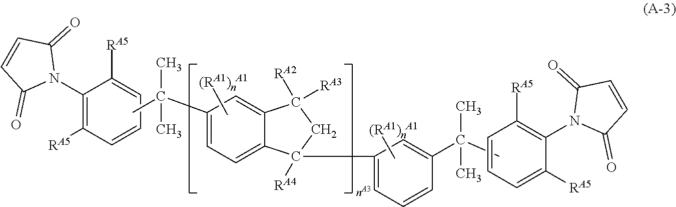

(In the formula, R^{A1} to R^{A5} and n^{A1} and n^{A3} are the same as in the general formula (A-2))

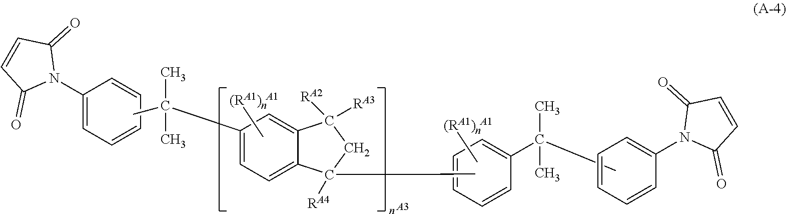

(In the formula, R^{A1} to R^{A4} and n^{A1} and n^{A3} are the same as in the general formula (A-2)).

Examples of the component (A) represented by the above general formula (A-3) include maleimide resins represented by the following general formula (A-3-1).

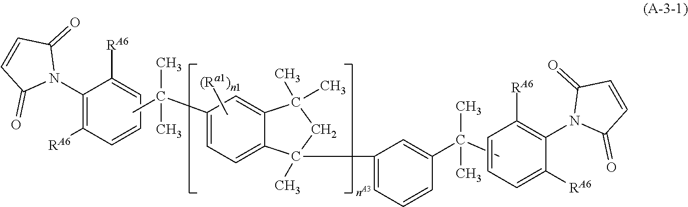

(In the formula, R^{A6} is each independently a methyl group, an ethyl group, an isopropyl group. n^{A3} is the same as defined above in the general formula (A-2)).

The component (A) represented by the general formula (A-4) is more preferably one represented by the following general formula (A-4-1) from the viewpoints of dielectric characteristic, conductor adhesion, solvent solubility, and ease of production.

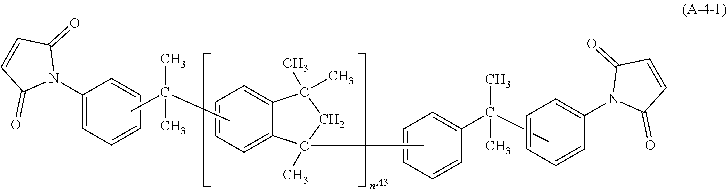

(In the formula, n^{A3} is the same as defined above in the general formula (A-2)).

As the derivatives of maleimide resins having a group containing a fused ring of an aromatic ring and an aliphatic ring and two or more N-substituted maleimide groups, for example, an aminomaleimide resin containing a structure derived from the maleimide resin exemplified as the component (A) and a structure derived from a diamine compound is preferred.

The aminomaleimide resin can be produced, for example, by subjecting the maleimide resin exemplified as the component (A) and a diamine compound to a Michael addition reaction.

Examples of the diamine compound include aromatic diamine compounds having two amino groups directly bonded to an aromatic ring, such as 4,4′-diaminodiphenylmethane, 3,3′-dimethyl-4,4′-diaminodiphenylmethane, 3,3′-diethyl-4,4′-diaminodiphenylmethane, 2,2-bis[4-(4-aminophenoxy)phenyl]propane, 4,4′-[1,3-phenylenebis(1-methylethylidene)]bisaniline, and 4,4′-[1,4-phenylenebis(1-methylethylidene)]bisaniline; and silicone compounds having two primary amino groups.

The number-average molecular weight (Mn) of the component (A) is not particularly limited, but is preferably 600 to 3,000, more preferably 800 to 2,000, and still more preferably 1,000 to 1,500, from the viewpoint of compatibility with other resins, conductor adhesion, and heat resistance.

The content of the component (A) in the resin composition of the present embodiment is not particularly limited, but is preferably 10 to 80% by mass, more preferably 30 to 75% by mass, and still more preferably 50 to 70% by mass with respect to the total amount (100% by mass) of the resin components in the resin composition of the present embodiment.

When the content of the component (A) is equal to or greater than the lower limit value, the heat resistance, moldability, processability, and conductor adhesion tend to be more easily improved. On the other hand, when the content of the component (A) is equal to or less than the upper limit value, the dielectric characteristic tends to be more easily improved.

### <Component (A′)>

Further, the resin composition of the present embodiment may be (A′) one or more selected from the group consisting of maleimide resins having one or more N-substituted maleimide groups and derivatives of the maleimide resins, and may contain one other than the component (A).

The component (A′) is preferably a maleimide resin represented by the following general formula (A′-1).

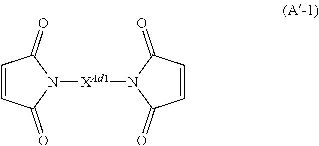

(In the formula, X^{Ad1} is a divalent organic group that does not contain a fused ring of an aromatic ring and an aliphatic ring).

X^{Ad1} in the above general formula (A′-1) is a divalent organic group that does not contain a fused ring of an aromatic ring and an aliphatic ring.

Examples of the divalent organic group represented by X^{Ad1} in the general formula (A′-1) include a divalent group represented by the following general formula (A′-2), a divalent group represented by the following general formula (A′-3), a divalent group represented by the following general formula (A′-4), a divalent group represented by the following general formula (A′-5), and a divalent group represented by the following general formula (A′-6).

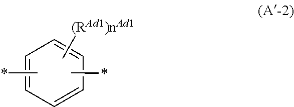

(In the formula, R^{Ad1} is an aliphatic hydrocarbon group having 1 to 5 carbon atoms or a halogen atom; n^{Ad1} is an integer of 0 to 4; and * represents a binding site).

Examples of the aliphatic hydrocarbon group having 1 to 5 carbon atoms represented by R^{Ad1} in the general formula (A-2) include alkyl groups having 1 to 5 carbon atoms such as a methyl group, an ethyl group, a n-propyl group, an isopropyl group, a n-butyl group, an isobutyl group, a t-butyl group, and a n-pentyl group; alkenyl groups having 2 to 5 carbon atoms; and alkynyl groups having 2 to 5 carbon atoms. The aliphatic hydrocarbon group having 1 to 5 carbon atoms may be either linear or branched.

Examples of the halogen atom include a fluorine atom, a chlorine atom, a bromine atom, and an iodine atom.

When n^{Ad1} is an integer of 2 or more, a plurality of R^{Ad1} 's may be the same as or different from each other.

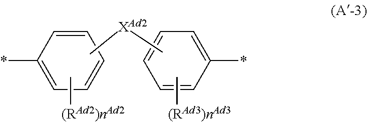

(In the formula, R^{Ad2} and R^{Ad3} are each independently an aliphatic hydrocarbon group having 1 to 5 carbon atoms or a halogen atom; X^{Ad2} is an alkylene group having 1 to 5 carbon atoms, an alkylidene group having 2 to 5 carbon atoms, an ether group, a sulfide group, a sulfonyl group, a carbonyloxy group, a keto group, a single bond, or a divalent group represented by the following general formula (A′-3-1); n^{Ad2} and n^{Ad3} are each independently an integer of 0 to 4; and * represents a binding site).

The aliphatic hydrocarbon group having 1 to 5 carbon atoms or halogen atom represented by R^{Ad2} and R^{Ad3} in the above general formula (A′-3) is explained in the same manner as that represented by R^{Ad1} in the above general formula (A′-2).

Examples of the alkylene group having 1 to 5 carbon atoms represented by X^{Ad2} in the general formula (A′-3) include a methylene group, a 1,2-dimethylene group, a 1,3-trimethylene group, a 1,4-tetramethylene group, and a 1,5-pentamethylene group.

Examples of the alkylidene group having 2 to 5 carbon atoms represented by X^{Ad2} in the general formula (A′-3) include an ethylidene group, a propylidene group, an isopropylidene group, a butylidene group, an isobutylidene group, a pentylidene group, and an isopentylidene group.

When n^{Ad2} or n^{Ad3} is an integer of 2 or more, a plurality of R^{Ad2}'s or a plurality of R^{Ad3}'s may be the same as or different from each other.

The divalent group represented by the general formula (A′-3-1) represented by X^{Ad2} in the general formula (A-3) is as follows.

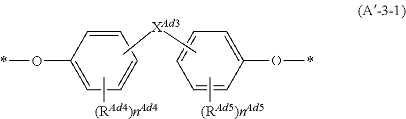

(In the formula, R^{Ad4} and R^{Ad5} are each independently an aliphatic hydrocarbon group having 1 to 5 carbon atoms or a halogen atom; X^{Ad3} is an alkylene group having 1 to 5 carbon atoms, an alkylidene group having 2 to 5 carbon atoms, an ether group, a sulfide group, a sulfonyl group, a carbonyloxy group, a keto group, or a single bond; n^{Ad4} and n^{Ad5} are each independently an integer of 0 to 4; and * represents a binding site).

The aliphatic hydrocarbon group having 1 to 5 carbon atoms or halogen atom represented by R^{Ad4} and R^{Ad5} in the above general formula (A′-3-1) is explained in the same manner as that represented by R^{Ad1} in the above general formula (A′-2).

The alkylene group having 1 to 5 carbon atoms and the alkylidene group having 2 to 5 carbon atoms represented by X^{Ad3} in the above general formula (A′-3-1) are explained in the same manner as those represented by X^{Ad2} in the above general formula (A′-3).

When n^{Ad4} or n^{Ad5} is an integer of 2 or more, a plurality of R^{Ad4}'s or a plurality of R^{Ad5}'s may be the same as or different from each other.

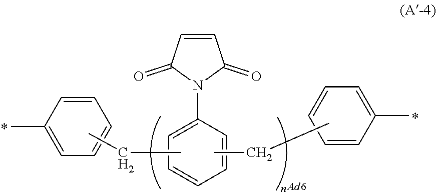

(In the formula, n^{Ad6} is an integer of 0 to 10; and * represents a binding site).

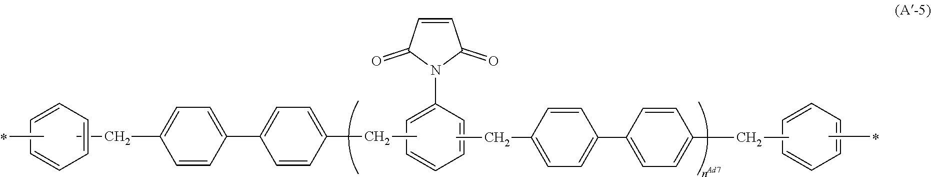

(In the formula, n^{Ad7} is a number of 0 to 5; and * represents a binding site).

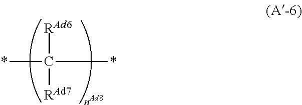

(In the formula, R^{Ad6} and R^{Ad7} are each independently a hydrogen atom or an aliphatic hydrocarbon group having 1 to 5 carbon atoms; n^{Ad8} is an integer of 1 to 8; and * represents a binding site).

The aliphatic hydrocarbon group having 1 to 5 carbon atoms represented by R^{Ad6} and R^{Ad7} in the above general formula (A′-6) is explained in the same manner as that represented by R^{Ad1} in the above general formula (A′-2).

When n^{Ad8} is an integer of 2 or more, a plurality of R^{Ad6}'s or a plurality of R^{Ad7}'s may be the same as or different from each other.

Examples of the component (A′) include aromatic bismaleimide resins, aromatic polymaleimide resins, and aliphatic maleimide resins. Among these, as the component (A′), aromatic polymaleimide resins are preferred, and biphenylaralkyl type maleimide resins are more preferred.

As the derivatives of maleimide resins having one or more of N-substituted maleimide groups, an aminomaleimide resin containing a structure derived from the maleimide resin exemplified as the component (A′) and a structure derived from a diamine compound is preferred.

The aminomaleimide resin can be produced, for example, by subjecting the maleimide resin exemplified as the component (A′) and a diamine compound to a Michael addition reaction.

Examples of the diamine compound include the same ones as the diamine compounds exemplified as the raw material components of the derivatives of maleimide resins having a group containing a fused ring of an aromatic ring and an aliphatic ring and two or more N-substituted maleimide groups, which was explained as the component (A).

When the component (A) and the component (A′) are used in combination, the content of the component (A) is not particularly limited with respect to the total amount (100% by mass) of the component (A) and the component (A′), but is preferably 20% by mass or more, more preferably 50% by mass or more, and still more preferably 70% by mass or more.

When the content of the component (A) is equal to or greater than the lower limit value, a lower lowest melt viscosity tends to be obtained. In addition, the upper limit of the content of the component (A) may be 99% by mass or less, 90% by mass or less, 85% by mass or less, or 80% by mass or less, with respect to the total amount (100% by mass) of the component (A) and the component (A′).

The content of the component (A′) is not particularly limited with respect to the total amount (100% by mass) of the component (A) and the component (A′), but is preferably 5 to 80% by mass, more preferably 10 to 50% by mass, and still more preferably 20 to 30% by mass.

When the content of component (A′) is within the above range, the characteristics of the component (A) and the component (A′) tend to be easily and sufficiently exhibited.

### (Total Content of Component (A) and Component (A′))

The total content of the component (A) and component (A′) in the resin composition of the present embodiment is not particularly limited, but is preferably 20 to 97% by mass, more preferably 50 to 95% by mass, and still more preferably 70 to 90% by mass with respect to the total amount (100% by mass) of the resin components in the resin composition of the present embodiment.

When the total content of the component (A) and the content (A′) is equal to or greater than the lower limit value, the heat resistance, moldability, processability, and conductor adhesion tend to be more easily improved. On the other hand, when the total content of the component (A) and the component (A′) is equal to or less than the upper limit value, the dielectric characteristic tends to be more easily improved.

Here, in the present description herein, the “resin component” means a resin and a compound which forms a resin by a curing reaction.

For example, in the resin composition of the present embodiment, the component (A), the component (A′), the component (C) and the component (D) correspond to resin components.

In a case where the resin composition of the present embodiment contains, as an optional component, a resin or a compound that forms a resin by a curing reaction in addition to the above-described components, these optional components are also included in the resin component.

However, the component (B), the component (E), and a component (F) are not included in the resin component.

The content of the resin component in the resin composition of the present embodiment is not particularly limited, but is preferably 20 to 95% by mass, more preferably 40 to 92% by mass, and still more preferably 70 to 90% by mass with respect to the total amount (100% by mass) of solid content of the resin composition of the present embodiment.

When the content of the resin component is equal to or greater than the lower limit value, the heat resistance, moldability, processability, and conductor adhesion tend to be more easily improved. On the other hand, when the content of the resin component is equal to or less than the upper limit value, the low thermal expansion tends to be more easily improved.

### <(B) Phosphate Ester Compound>

The phosphate ester compound (B) is a phosphate ester compound which has two or more phosphorus atoms, in which the group connecting at least two of the phosphorus atoms contains two or more aromatic rings.

The phosphate ester compound (B) may be used alone or in combination of two or more kinds thereof.

The resin composition of the present embodiment can have a low lowest melt viscosity by containing the phosphate ester compound (B), even though a maleimide resin is used as a thermosetting resin.

Although the reason for this is unclear, it is assumed that one factor is that the phosphate ester compound (B) traps radicals present in the system when the resin composition is melted, thereby suppressing the curing reaction of component (A).

The number of phosphorus atoms contained in the phosphate ester compound (B) is 2 or more, preferably 2 to 10, more preferably 2 to 5, and still more preferably 2 or 3.

As phosphorus atoms contained in the phosphate ester compound (B), at least one phosphorus atom forms a phosphate ester bond, and it is preferred that all of the phosphorus atoms form phosphate ester bonds.

Here, in the present description, the term “phosphate ester bond” refers to a bond represented by any one of the following formulas (B-3) to (B-5). Among these, it is preferable that the phosphate ester bond represented by the following formula (B-5) is formed.

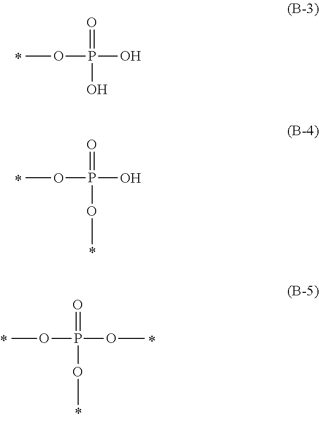

(In the formulas, * is the site bonded to the organic group).

Examples of the organic group bonded to the phosphate ester bond include an aliphatic hydrocarbon group and an aromatic hydrocarbon group. Among these, an aromatic hydrocarbon group is preferred. That is, the phosphate ester compound (B) is preferably an aromatic phosphate ester compound.

Examples of the aromatic hydrocarbon group bonded to a phosphate ester bond include a substituted or unsubstituted phenyl group, and a substituted or unsubstituted naphthyl group. Examples of the substituent include hydrocarbon groups having 1 to 5 carbon atoms, such as a methyl group, an ethyl group, a n-propyl group, an isopropyl group, a n-butyl group, an isobutyl group, a t-butyl group, and a n-pentyl group; and halogen atoms. Among these, an unsubstituted phenyl group or a 2,5-dimethylphenyl group is preferred.

In the component (B), the group connecting two phosphorus atoms contain two or more aromatic rings.

From the viewpoint of the lowest melt viscosity, the two or more aromatic rings preferably form a divalent aromatic hydrocarbon group having a structure in which two or more aromatic rings are bonded by a single bond or a linking group having 5 or less carbon atoms (hereinafter also referred to as an “aromatic hydrocarbon group (Z1)”), or a divalent fused polycyclic aromatic hydrocarbon group containing two or more aromatic rings (hereinafter also referred to as an “aromatic hydrocarbon group (Z2)”), and more preferably form an aromatic hydrocarbon group (Z1).

### (Aromatic Hydrocarbon Group (Z1))

Examples of two or more aromatic rings contained in the aromatic hydrocarbon group (Z1) include a benzene ring, a naphthalene ring, and an anthracene ring, and among these, a benzene ring is preferable.

Examples of linking groups having 5 or less carbon atoms, which may be contained in the aromatic hydrocarbon group (Z1), include divalent hydrocarbon groups having 1 to 5 carbon atoms, divalent heteroatom-containing groups having 5 or less carbon atoms, and divalent groups having 1 to 5 carbon atoms in which a hydrocarbon group and a heteroatom-containing group are linked together. Here, “having 5 or less carbon atoms” also includes a case having 0 carbon atom.

Examples of the divalent hydrocarbon group having 1 to 5 carbon atoms include alkylene groups having 1 to 5 carbon atoms, such as a methylene group, a 1,2-dimethylene group, a 1,3-trimethylene group, a 1,4-tetramethylene group, and a 1,5-pentamethylene group; and alkylidene groups having 2 to 5 carbon atoms, such as an ethylidene group, a propylidene group, an isopropylidene group, a butylidene group, an isobutylidene group, a pentylidene group, and an isopentylidene group. Examples of the divalent heteroatom-containing group having 5 or less carbon atoms include an ether group, a sulfide group, a sulfonyl group, a carbonyloxy group, and a keto group.

From the viewpoint of the lowest melt viscosity, the aromatic hydrocarbon group (Z1) is preferably a divalent group represented by the following general formula (B-2).

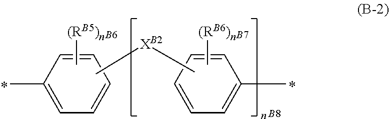

(In the formula, R^{B5} and R^{B6} are each independently an aliphatic hydrocarbon group having 1 to 5 carbon atoms or a halogen atom; X^{B2} is an alkylene group having 1 to 5 carbon atoms, an alkylidene group having 2 to 5 carbon atoms, an ether group, a sulfide group, a sulfonyl group, a carbonyloxy group, a keto group, or a single bond; n^{B6} and n^{B7} are each independently an integer of 0 to 4; n^{B8} is an integer of 1 to 3; and * represents a binding site).

Examples of the alkylene group having 1 to 5 carbon atoms represented by X^{B2} in the general formula (B-2) include a methylene group, a 1,2-dimethylene group, a 1,3-trimethylene group, a 1,4-tetramethylene group, and a 1,5-pentamethylene group.

Examples of the alkylidene group having 2 to 5 carbon atoms represented by X^{B2} include an ethylidene group, a propylidene group, an isopropylidene group, a butylidene group, an isobutylidene group, a pentylidene group, and an isopentylidene group.

Among the groups represented by X^{B2}, a methylene group, an isopropylidene group and a single bond are preferred, and a single bond is more preferred.

Examples of the aliphatic hydrocarbon group having 1 to 5 carbon atoms represented by R^{B5} and R^{B6} in the general formula (B-2) include a methyl group, an ethyl group, a n-propyl group, an isopropyl group, a n-butyl group, an isobutyl group, a t-butyl group, and a n-pentyl group.

In the general formula (B-2), n^{B6} and n^{B7} are preferably integers of 0 to 3, more preferably 0 or 1, and still more preferably 0.

When n^{B6} or n^{B7} is an integer of 2 or more, a plurality of R^{B5}'s or a plurality of R^{B6}'s may be the same as or different from each other.

n^{B8} in the general formula (B-2) is more preferably an integer of 1 or 2, and still more preferably 1.

When n^{B8} is an integer of 2 or more, a plurality of X^{B2}'s or a plurality of n^{B7}'s may be the same as or different from each other.

The divalent group represented by the above general formula (B-2) is preferably a divalent group represented by the following formula (B-2-1) or a divalent group represented by the following formula (B-2-2), and more preferably a divalent group represented by the following formula (B-2-2).

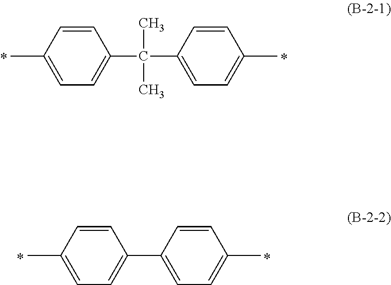

(In the formulas, * denotes a binding site).

### (Aromatic Hydrocarbon Group (Z2))

The aromatic hydrocarbon group (Z2) is a divalent fused polycyclic aromatic hydrocarbon group containing two or more aromatic rings. In this embodiment, the “fused polycyclic aromatic hydrocarbon” refers to an aromatic hydrocarbon having two or more ring structures, in which two or more rings have fused rings sharing two or more atoms, and examples thereof include naphthalene, anthracene, and pyrene. Therefore, examples of the aromatic hydrocarbon group (Z2) include divalent groups obtained by removing two hydrogen atoms from these fused polycyclic aromatic hydrocarbons. These fused polycyclic aromatic hydrocarbons may or may not be substituted with a substituent. Examples of the substituent include the same as the substituent that may be contained in the aromatic ring contained in the aromatic hydrocarbon group (Z1).

The phosphate ester compound is preferably a compound represented by the following general formula (B-1).

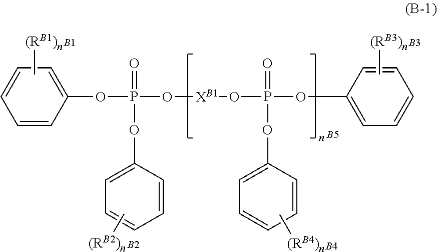

(In the formula, R^{B1} to R^{B4} are each independently an aliphatic hydrocarbon group having 1 to 5 carbon atoms or a halogen atom; X^{B1} is a divalent group containing two or more aromatic rings; n^{B1} to n^{B4} are each independently an integer of 0 to 5; and n^{B5} is an integer of 1 to 5).

Examples of the aliphatic hydrocarbon group having 1 to 5 carbon atoms represented by R^{B1} and R^{B4} in the general formula (B-1) include a methyl group, an ethyl group, a n-propyl group, an isopropyl group, a n-butyl group, an isobutyl group, a t-butyl group, and a n-pentyl group. As the aliphatic hydrocarbon group, an aliphatic hydrocarbon group having 1 to 3 carbon atoms is preferable, an alkyl group having 1 to 3 carbon atoms is more preferable, and a methyl group is still more preferable.

n^{B1} to n^{B4} in the general formula (B-1) is preferably 0 to 2, and more preferably 0 or 2. When n^{B1} to n^{B4} are each an integer of 2 or more, a plurality of R^{B1}'s, R^{B2}'s, R^{B3}'s, or R^{B4}'s may be the same as or different from each other.

In the general formula (B-1), n^{B5} is an integer of 1 to 5, preferably an integer of 1 to 3, more preferably an integer of 1 or 2, and still more preferably 1. When n^{B5} is an integer of 2 or more, a plurality of X^{B1}'s or a plurality of n^{B4}'s may be the same as or different from each other.

Examples of the divalent group containing two or more aromatic rings represented by X^{B1} in the above general formula (B-1) include the above aromatic hydrocarbon group (Z1) and aromatic hydrocarbon group (Z2). Among these, X^{B1} is preferably an aromatic hydrocarbon group (Z1), more preferably a divalent group represented by the above general formula (B-2), and still more preferably a divalent group represented by the above formula (B-2-2).

Examples of the phosphate ester compound (B) include 4,4′-biphenol-diphenyl phosphate, bisphenol A-diphenyl phosphate, 4,4′-biphenol-dicresyl phosphate, bisphenol A-dicresyl phosphate, 4,4′-biphenol-di(2,6-xylenyl phosphate), bisphenol A-di(2,6-xylenyl phosphate), 4,4′-biphenol-polyphenyl phosphate, bisphenol A-polyphenyl phosphate, 4,4′-biphenol-polycresyl phosphate, bisphenol A-polycresyl phosphate, 4,4′-biphenol-poly(2,6-xylenyl phosphate), and bisphenol A-poly(2,6-xylenyl phosphate). Among these, 4,4′-biphenol-di(2,6-xylenyl phosphate) is preferred.

In addition, “poly” in the above example compounds means a compound having 2 or more repeating units (for example, in the above general formula (B-1), the structural unit whose structural unit number is indicated by n^{B5}) containing a structure derived from a divalent phenol compound and a structure derived from phosphoric acid that constitute the phosphate ester compound, and may also mean a compound in which the average value of the repeating units exceeds 1 by containing such a compound.

The average particle diameter (D₅₀) of the phosphate ester compound (B) is not particularly limited, but is preferably 0.1 to 10 μm, more preferably 0.3 to 5 μm, and still more preferably 0.5 to 3 μm, from the viewpoint of the dispersibility and handling ability. Here, the average particle diameter (D₅₀) in the present description is a particle diameter at a point corresponding to 50% by volume when a cumulative frequency distribution curve based on the particle diameter is obtained with the total volume of the particles as 100%.

### (Content of Phosphate Ester Compound (B))

The content of the phosphate ester compound (B) in the resin composition of the present embodiment is not particularly limited, but is preferably 0.1 to 10 parts by mass, more preferably 0.2 to 7 parts by mass, and still more preferably 0.3 to 4 parts by mass, with respect to the total amount (100 parts by mass) of the resin components in the resin composition of the present embodiment.

When the content of the phosphate ester compound (B) is the lower limit value or more, the lowest melt viscosity tends to be more easily improved. In addition, when the content of the phosphate ester compound (B) is the upper limit value or less, the conductor adhesion tends to be more easily improved.

### <(C) Compound Having Two or More Functional Groups Containing an Ethylenically Unsaturated Bond>

The resin composition of the present embodiment preferably further contains (C) a compound having two or more functional groups containing an ethylenically unsaturated bond.

By containing the component (C), the resin composition of the present embodiment tends to easily obtain more excellent dielectric characteristics.

Note that in the present description, the term “ethylenically unsaturated bond” means a carbon-carbon double bond capable of an addition reaction, and does not include a double bond of an aromatic ring.

Hereinafter, a functional group containing an ethylenically unsaturated bond may be referred to as an “ethylenically unsaturated group”.

Examples of the ethylenically unsaturated group include a vinyl group, an allyl group, a 1-methylallyl group, an isopropenyl group, a 2-butenyl group, a 3-butenyl group, a styryl group, a maleimide group, and a (meth)acryloyl group.

The component (C) may be used alone or may be used in combination of two or more kinds thereof.

As the component (C), from the viewpoint of obtaining superior dielectric characteristics, a polymer having two or more functional groups containing an ethylenically unsaturated bond is preferred.

Examples of the polymer having two or more functional groups containing an ethylenically unsaturated bond include (C1) a conjugated diene polymer having two or more ethylenically unsaturated groups (hereinafter also simply referred to as “(C1) conjugated diene polymer”), (C2) a modified conjugated diene polymer having two or more ethylenically unsaturated groups (hereinafter also simply referred to as “(C2) modified conjugated diene polymer”), and (C3) a polyphenylene ether having two or more ethylenically unsaturated groups (hereinafter also simply referred to as “(C3) modified polyphenylene ether”).

Note that, in the description herein, the “conjugated diene polymer” means a polymer of a conjugated diene compound.

Hereinafter, the components (C1) to (C3) will be explained.

### (Conjugated Diene Polymer (C1))

The conjugated diene polymer (C1) is a conjugated diene polymer having two or more ethylenically unsaturated groups.

The conjugated diene polymer (C1) preferably has a vinyl group as an ethylenically unsaturated group in a side chain, from the viewpoint of compatibility with other resins and dielectric characteristics.

The number of the side chain vinyl groups contained in one molecule of the conjugated diene polymer (C1) is not particularly limited, but is preferably 2 or more, more preferably 5 or more, and still more preferably 10 or more, from the viewpoint of compatibility with other resins and dielectric characteristics, and may be 100 or less, 80 or less, or 60 or less.

Examples of the conjugated diene polymer (C1) include polybutadiene having a 1,2-vinyl group, butadiene-styrene copolymer having a 1,2-vinyl group, and polyisoprene having a 1,2-vinyl group. Among these, polybutadiene having a 1,2-vinyl group is preferred from the viewpoints of dielectric characteristic and heat resistance. The polybutadiene having a 1,2-vinyl group is preferably a polybutadiene homopolymers having 1,2-vinyl groups.

The 1,2-vinyl group derived from butadiene contained in the conjugated diene polymer (C1) is a vinyl group contained in the structural unit derived from 1,3-butadiene represented by the following formula (C1-1).

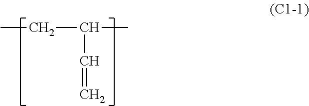

When the conjugated diene polymer (C1) is polybutadiene having a 1,2-vinyl group, the content of the structural unit having a 1,2-vinyl group (hereinafter, also referred to as “vinyl group content”) based on the total structural units derived from butadiene constituting the polybutadiene is not particularly limited, but is preferably 50 mol % or more, more preferably 70 mol % or more, and still more preferably 85 mol % or more, from the viewpoint of compatibility with other resins, dielectric characteristics, and heat resistance. The upper limit of the vinyl group content is not particularly limited, and may be 100 mol % or less, may be 95 mol % or less, or may be 90 mol % or less.

The number-average molecular weight (Mn) of the conjugated diene polymer (C1) is not particularly limited, but is preferably 400 to 3,000, more preferably 600 to 2,000, and still more preferably 800 to 1,500, from the viewpoint of compatibility with other resins, dielectric characteristics, and heat resistance.

### (Modified Conjugated Diene Polymer (C2))

The modified conjugated diene polymer (C2) is a modified conjugated diene polymer having two or more ethylenically unsaturated groups.

The modified conjugated diene polymer (C2) is preferably one obtained by modifying the conjugated diene polymer (C1) with a maleimide resin having two or more N-substituted maleimide groups (hereinafter, also simply referred to as “maleimide resin”).

As the conjugated diene polymer (C1) which is the raw material for the modified conjugated diene polymer (C2), a conjugated diene polymer having a vinyl group in a side chain is preferable.

As the maleimide resin which is the raw material of the modified conjugated diene polymer (C2), those exemplified as the component (A) and the component (A′) can be used, and the preferred embodiments are also the same.

The modified conjugated diene polymer (C2) preferably has, in a side chain, a substituent formed by a reaction between a side chain vinyl group of a conjugated diene polymer having a vinyl group in a side chain and an N-substituted maleimide group of a maleimide resin [hereinafter, sometimes referred to as a “maleimide resin-derived substituent”], more preferably has, in a side chain, a maleimide resin-derived substituent and a vinyl group.

The maleimide resin-derived substituent is preferably a group containing a structure represented by the following general formula (C2-1) or (C2-2) as a structure derived from a maleimide resin, from the viewpoint of compatibility with other resins, dielectric characteristics, low thermal expansion properties, and heat resistance.

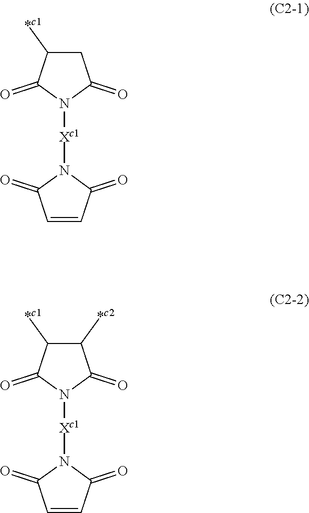

In the formula, X^{C1} is a divalent group obtained by removing two N-substituted maleimide groups from a maleimide resin, *^{C1} is a site bonded to a carbon atom derived from a side chain vinyl group of a conjugated diene polymer having a vinyl group in a side chain, and *^{C2} is a site bonded to another atom.

A number-average molecular weight (Mn) of the modified conjugated diene polymer (C2) is not particularly limited, and is preferably 700 to 6,000, more preferably 800 to 5,000, still more preferably 1,000 to 2,500.

The reaction conditions for the conjugated diene polymer (C1) and the maleimide resin are not particularly limited, and for example, the modified conjugated diene polymer (C2) can be obtained by charging a raw material and an organic solvent into a reaction vessel, and allowing them to react while heating and stirring are performed as necessary.

The ratio (Mm/Mv) of the number of moles (Mm) of the N-substituted maleimide group in the maleimide resin to the number of moles (Mv) of the side chain vinyl group in the conjugated diene polymer having a vinyl group in a side chain during the reaction is not particularly limited, but is preferably 0.001 to 0.5, more preferably 0.005 to 0.1, and still more preferably 0.008 to 0.05 from the viewpoint of compatibility with other resins of the resulting modified conjugated diene polymer (C2) and suppression of gelation of the product during the reaction.

### (Modified Polyphenylene Ether (C3))

The modified polyphenylene ether (C3) is a polyphenylene ether having two or more ethylenically unsaturated groups.

The modified polyphenylene ether (C3) is not particularly limited, but is preferably one having a structural unit represented by the following general formula (C3-1).

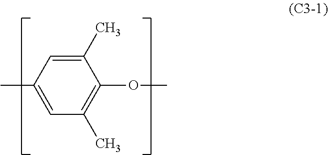

The ethylenically unsaturated group contained in the modified polyphenylene ether (C3) is preferably a (meth)acryloyl group, and more preferably a methacryloyl group.

The number of ethylenically unsaturated groups in the modified polyphenylene ether (C3) is not particularly limited, but from the viewpoints of heat resistance and flowability, it is preferably 1 to 5, more preferably 2 to 3, and still more preferably 2.

The modified polyphenylene ether (C3) preferably has an ethylenically unsaturated group at least one end, more preferably has it at both ends, and still more preferably has it only at both ends.

A weight-average molecular weight (Mw) of the modified polyphenylene ether (C3) is not particularly limited, and is preferably 500 to 7,000, more preferably 800 to 5,000, still more preferably 1,000 to 3,000, and particularly preferably 1,200 to 2,500.

### (Content of Component (C))

In the resin composition of the present embodiment, the content of the component (C) is not particularly limited, but is preferably 1 to 50% by mass, more preferably 5 to 30% by mass, and still more preferably 8 to 20% by mass with respect to the total amount (100% by mass) of the resin components in the resin composition of the present embodiment.

When the content of the component (C) is equal to or greater than the lower limit value, the dielectric characteristics tend to be more easily improved. When the content of the component (C) is equal to or less than the upper limit value, the heat resistance, moldability, processability, and conductor adhesion tend to be more easily improved.

### <Styrene-Based Thermoplastic Resin (D)>

It is preferable that the resin composition of the present embodiment further contains a styrene-based thermoplastic resin (D).

By containing the styrene-based thermoplastic resin (D), the resin composition of the present embodiment tends to easily obtain more excellent dielectric characteristics.

The styrene-based thermoplastic resin (D) may be used alone or may be used in combination of two or more kinds thereof.

The styrene-based thermoplastic resin (D) has a structural unit derived from a styrene-based compound. Examples of the styrene-based compound include styrene; and alkyl-substituted styrenes such as α-methylstyrene, o-methylstyrene, m-methylstyrene, and p-methylstyrene. The number of carbon atoms in the alkyl group contained in the alkyl-substituted styrene is not particularly limited, but is preferably 1 to 5, more preferably 1 to 3, and even more preferably 1 or 2.

In the styrene-based thermoplastic resin (D), the content of structural units derived from a styrene-based compound [hereinafter, sometimes also referred to as “styrene content”] is not particularly limited, but from the viewpoints of dielectric characteristics, conductor adhesion, heat resistance, glass transition temperature, and low thermal expansion, it is preferably 5 to 60% by mass, more preferably 7 to 40% by mass, and still more preferably 10 to 20% by mass.

Examples of the structural units other than the structural units derived from the styrene-based compound contained in the styrene-based thermoplastic resin (D) include a structural unit derived from butadiene, a structural unit derived from isoprene, a structural unit derived from maleic acid, and a structural unit derived from maleic anhydride.

Examples of the styrene-based thermoplastic resin (D) include hydrogenated products of styrene-butadiene-styrene block copolymers (SEBS, SBBS), hydrogenated products of styrene-isoprene-styrene block copolymers (SEPS), and styrene-maleic anhydride copolymers (SMA), and among these, hydrogenated products of styrene-butadiene-styrene block copolymers (SEBS) are preferred.

A number-average molecular weight (Mn) of the styrene-based thermoplastic resin (D) is not particularly limited, and is preferably 10,000 to 500,000, more preferably 50,000 to 350,000, still more preferably 100,000 to 200,000.

### <Content of Styrene-Based Thermoplastic Resin (D)>

In the resin composition of the present embodiment, the content of the styrene-based thermoplastic resin is not particularly limited, but is preferably 1 to 50% by mass, more preferably 5 to 30% by mass, and still more preferably 8 to 20% by mass with respect to the total amount (100% by mass) of the resin components in the resin composition of the present embodiment.

When the content of the styrene-based thermoplastic resin (D) is equal to or greater than the lower limit value, the dielectric characteristics tend to be more easily improved. When the content of the styrene-based thermoplastic resin (D) is equal to or less than the upper limit value, the heat resistance, moldability, processability, and conductor adhesion tend to be more easily improved.

### <Inorganic Filler (E)>

It is preferable that the resin composition of the present embodiment further contains an inorganic filler (E).

By containing the inorganic filler (E), the resin composition of the present embodiment tends to easily obtain more excellent low thermal expansion and heat resistance.

The inorganic filler (E) may be used alone or may be used in combination of two or more kinds thereof.

Examples of the inorganic filler (E) include silica, alumina, titanium oxide, mica, beryllia, barium titanate, potassium titanate, strontium titanate, calcium titanate, aluminum carbonate, magnesium hydroxide, aluminum hydroxide, aluminum silicate, calcium carbonate, calcium silicate, magnesium silicate, silicon nitride, boron nitride, clay, talc, aluminum borate, and silicon carbide. Among these, from the viewpoint of low thermal expansion properties, heat resistance, and flame retardancy, silica, alumina, mica, and talc are preferable, silica and alumina are more preferable, and silica is still more preferable.

Examples of silica include crushed silica, fumed silica, and fused silica, and among these, fused silica is preferred from the viewpoints of dispersibility and moldability.

Examples of the shape of the inorganic filler (E) include a spherical shape and a crushed shape, and a spherical shape is preferable.

The inorganic filler (E) may be surface-treated with a coupling agent such as a silane coupling agent.

The average particle diameter (D₅₀) of the inorganic filler (E) is not particularly limited, but is preferably 0.01 to 20 μm, more preferably 0.1 to 10 μm, still more preferably 0.2 to 1 μm, and particularly preferably 0.3 to 0.8 μm, from the viewpoint of the dispersibility and fine wiring of the inorganic filler (E).

### (Content of Inorganic Filler (E))

When the resin composition of the present embodiment contains the inorganic filler (E), the content of the inorganic filler (E) in the resin composition of the present embodiment is not particularly limited, but is preferably 5 to 80% by mass, more preferably 7 to 50% by mass, and still more preferably 10 to 30% by mass with respect to the total amount (100% by mass) of solid content of the resin composition.

When the content of the inorganic filler (E) is equal to or more than the lower limit value, the low thermal expansion property and the heat resistance tend to be more favorable. On the other hand, when the content of the inorganic filler (E) is equal to or less than the upper limit value, the moldability and the conductor adhesion tend to be more favorable.

### <Curing Accelerator (F)>

It is preferable that the resin composition of the present embodiment further contains a curing accelerator (F).

By containing the curing accelerator (F), the resin composition of the present embodiment tends to have a improved curability and easily obtain more excellent dielectric characteristic, heat resistance, and conductor adhesion.

The curing accelerator (F) may be used alone or may be used in combination of two or more kinds thereof.

Examples of the curing accelerator (F) include acidic catalysts such as p-toluenesulfonic acid; amine compounds such as triethylamine, tributylamine, pyridine, and dicyandiamide; imidazole compounds such as methylimidazole, phenylimidazole, 1-cyanoethyl-2-phenylimidazole, and 1-cyanoethyl-2-phenylimidazolium trimellitate; isocyanate-masked imidazole compounds such as an addition reaction product of hexamethylene diisocyanate resin and 2-ethyl-4-methylimidazole; quaternary ammonium compounds; phosphorus-based compounds such as triphenylphosphine; organic peroxides such as dicumyl peroxide, 2,5-dimethyl-2,5-bis(t-butylperoxy) hexyne-3,2,5-dimethyl-2,5-bis(t-butylperoxy) hexane, t-butylperoxyisopropyl monocarbonate, and a, a′-bis(t-butylperoxy)diisopropylbenzene; and carboxylates of manganese, cobalt, and zinc. Among these, imidazole compounds and organic peroxides are preferred.

### (Content of Curing Accelerator (F))

When the resin composition of the present embodiment contains the curing accelerator (F), the content of the curing accelerator (F) is not particularly limited, but is preferably 0.01 to 10 parts by mass, more preferably 0.1 to 7 parts by mass, and still more preferably 0.5 to 5 parts by mass, with respect to the total amount (100 parts by mass) of the resin components in the resin composition of the present embodiment.

When the content of the curing accelerator (F) is equal to or greater than the lower limit value, sufficient curing acceleration effect tends to be obtained. On the other hand, when the content of the curing accelerator (F) is equal to or less than the upper limit value, storage stability tend to be more easily improved.

### <Other Components>

The resin composition of the present embodiment may further contain, if necessary, one or more selected from the group consisting of a resin material other than the above-mentioned components, an antioxidant, a thermal stabilizer, an antistatic agent, an ultraviolet absorber, a pigment, a colorant, a lubricant, a flame retardant, an organic solvent, and additives other than these. For each of these, one kind may be used alone, or two or more kinds may be used in combination. In addition, the use amount thereof is not particularly limited, and may be used in a range in which the effect of the present embodiment is not inhibited, if necessary.

### (Organic Solvent)

The resin composition of the present embodiment may contain an organic solvent from the viewpoint of facilitating handling and from the viewpoint of facilitating production of a prepreg to be described later.

The organic solvent may be used alone or may be used in combination of two or more kinds thereof.

In the description herein, a resin composition containing an organic solvent may be referred to as a resin varnish.

Examples of the organic solvent include, for example, alcohol-based solvents such as ethanol, propanol, butanol, methyl cellosolve, butyl cellosolve, and propylene glycol monomethyl ether; ketone-based solvents such as acetone, methyl ethyl ketone, methyl isobutyl ketone, and cyclohexanone; ether-based solvents such as tetrahydrofuran; aromatic hydrocarbon-based solvents such as toluene, xylene, and mesitylene; nitrogen atom-containing solvents such as dimethylformamide, dimethylacetamide, and N-methylpyrrolidone; sulfur atom-containing solvents such as dimethyl sulfoxide; and ester-based solvents such as γ-butyrolactone.

Among these, from the viewpoint of solubility, an alcohol-based solvent, a ketone-based solvent, a nitrogen atom-containing solvent, and an aromatic hydrocarbon-based solvent are preferable, an aromatic hydrocarbon-based solvent is more preferable, and toluene is still more preferable.

### <Method for Producing Resin Composition>

The resin composition of the present embodiment can be produced by mixing the respective components.

When mixing respective components, the respective components may be dissolved or dispersed while stirring. Conditions such as an order of mixing raw materials, a mixing temperature, and a mixing time are not particularly limited, and may be arbitrarily set according to the type of raw materials.

### [Prepreg]

The prepreg of the present embodiment is a prepreg containing the resin composition of the present embodiment or a semi-cured product of the resin composition.

The prepreg of the present embodiment contains, for example, the resin composition of the present embodiment or a semi-cured product of the resin composition and a sheet-shaped fiber base material.

As the sheet-shaped fiber base material contained in the prepreg of the present embodiment, for example, known sheet-shaped fiber base materials used in various laminated plates for electrical insulating materials can be used.

Examples of the material of the sheet-shaped fiber base material include inorganic fibers such as E glass, D glass, S glass, and Q glass; organic fibers such as polyimide, polyester, and tetrafluoroethylene; and mixtures thereof. These sheet-shaped fiber base materials have a shape of, for example, a woven fabric, a nonwoven fabric, a roving, a chopped strand mat, or a surfacing mat.

The prepreg of the present embodiment can be produced by, for example, impregnating or coating the resin composition of the present embodiment into a sheet-shaped fiber base material and then heating and drying the impregnated or coated resin composition to make it B-stage.

The temperature and time of the heating and drying are not particularly limited, but from the viewpoint of productivity and appropriate B-staging of the resin composition of the present embodiment, for example, the temperature and time can be set to 50 to 200° C. and 1 to 30 minutes.

The solid component concentration derived from the resin composition in the prepreg of the present embodiment is not particularly limited, but from the viewpoint of easily obtaining better moldability when a laminated plate is formed, the solid content concentration is preferably 20 to 90% by mass, more preferably 25 to 80% by mass, and still more preferably 30 to 75% by mass.

### [Resin Film]

The resin film of the present embodiment is a resin film containing the resin composition of the present embodiment or a semi-cured product of the resin composition.

The resin film of the present embodiment can be produced, for example, by applying the resin composition of the present embodiment containing an organic solvent, that is, a resin varnish, on a support and then heating and drying the coating.

Examples of the support include a plastic film, a metal foil, and a release paper.

The temperature and time of the heating and drying are not particularly limited, but from the viewpoint of productivity and appropriate B-staging of the resin composition of the present embodiment, the temperature and time can be set to 50 to 200° C. and 1 to 30 minutes.

The resin film of the present embodiment is preferably used for forming an insulating layer in the case of producing a printed wiring board.

### [Laminated Plate]

The laminated plate of the present embodiment is a laminated plate having a cured product of the resin composition of the present embodiment, and a metal foil.

The laminated plate having a metal foil may also be referred to as a metal-clad laminated plate.

The metal of the metal foil is not particularly limited, and examples thereof include copper, gold, silver, nickel, platinum, molybdenum, ruthenium, aluminum, tungsten, iron, titanium, chromium, and an alloy containing one or more kinds of these metal elements.

The laminated plate of the present embodiment can be produced, for example, by disposing a metal foil on one side or both sides of the prepreg of the present embodiment, and then subjecting the prepreg to heating and press molding.

Usually, the B-staged prepreg is cured by this heating and press molding to obtain the laminated plate of the present embodiment.

When the heating and press molding is performed, only one prepreg may be used, or two or more prepregs may be laminated and used.

For the heating and press molding, for example, a multi-stage press, a multi-stage vacuum press, a continuous molding, or an autoclave molding machine can be used.

The conditions of the heating and press molding are not particularly limited, but the temperature may be 100 to 300° C., the time may be 10 to 300 minutes, and the pressure may be 1.5 to 5 MPa, for example.

### [Printed Wiring Board]

The printed wiring board of the present embodiment is a printed wiring board having a cured product of the resin composition of the present embodiment.

The printed wiring board of the present embodiment can be produced, for example, by performing conductor circuit formation by a known method on one or more kinds of materials selected from the group consisting of a cured product of the prepreg of the present embodiment, a cured product of the resin film of the present embodiment, and a laminated plate. In addition, a multilayer printed wiring board can also be produced by further performing a multilayer adhesion process as necessary. The conductor circuit can be formed by, for example, appropriately performing a drilling process, a metal plating process, or etching of a metal foil.

### [Semiconductor Package]

The semiconductor package of the present embodiment is a semiconductor package having the printed wiring board of the present embodiment and a semiconductor element.

The semiconductor package of the present embodiment can be produced, for example, by mounting a semiconductor chip and a memory on the printed wiring board of the present embodiment by a known method.

### EXAMPLE

Hereinafter, the present embodiment will be specifically described with reference to Examples. However, the present embodiment is not limited to the following examples.

In each example, the number-average molecular weight (Mn) and the weight-average molecular weight (Mw) were measured by the following method.

By gel permeation chromatography (GPC), the number-average molecular weight (Mn) and the weight-average molecular weight (Mw) were converted from a calibration curve using standard polystyrene. The calibration curve was approximated by a cubic equation using standard polystyrene: TSK standard POLYSTYRENE (Type; A-2500, A-5000, F-1, F-2, F-4, F-10, F-20, F-40) [manufactured by Tosoh Corporation, trade name]. The measurement conditions of GPC are shown below.
Device:
Pump: L-6200 type (manufactured by Hitachi High-Tech Corporation)
Detector: L-3300 type RI (manufactured by Hitachi High-Tech Corporation)
Column oven: L-655A-52 (manufactured by Hitachi High-Tech Corporation)
Column: Guard column; TSK Guardcolumn HHR-L+column; TSKgel G4000HHR+TSKgel G2000HHR (all manufactured by Tosoh Corporation, trade name)
Column size: 6.0×40 mm (guard column), 7.8×300 mm (column)
Eluent: tetrahydrofuran
Sample concentration: 30 mg/5 ml
Injection amount: 20 μL
Flow rate: 1.00 mL/min
Measurement temperature: 40° C.

### [Production of Modified Conjugated Diene Polymer]

### Production Example 1

33.8 parts by mass of polybutadiene (1,2-polybutadiene homopolymer, number-average molecular weight (Mn)=1,200, vinyl group content=85 mol % or more), 1.43 parts by mass of bismaleimide resin (aromatic bismaleimide resin having a group containing an indane ring: number-average molecular weight (Mn) 1,300, the same as maleimide resin 1 described later), 0.0035 parts by mass of α,α′-bis(t-butylperoxy)diisopropylbenzene, and toluene as an organic solvent were charged into a glass flask container having a volume of 2 L capable of being heated and cooled and equipped with a thermometer, a reflux cooling pipe, and a stirring device. Next, the mixture was reacted under stirring in a nitrogen atmosphere at 90 to 100° C. for 5 hours to obtain a solution of a modified conjugated diene polymer (solid content concentration: 35% by mass). The number-average molecular weight (Mn) of the resulting modified conjugated diene polymer was 2,000.

Furthermore, the solution containing polybutadiene and bismaleimide resin before the start of the reaction and the solution after the reaction were subjected to GPC measurement by the above method, and the peak areas derived from the bismaleimide resin before and after the reaction were determined. Next, the modification ratio of the vinyl group in the bismaleimide resin was calculated according to the following formula. The modification ratio of the vinyl group corresponds to the rate of decrease in the peak area derived from the bismaleimide resin due to the reaction.

The modification ratio of the vinyl group (%)=[(peak area derived from bismaleimide resin before reaction)−(peak area derived from bismaleimide resin after reaction)]×100/(peak area derived from bismaleimide resin before reaction)

The modification ratio of vinyl group calculated from the above formula was 40%.

### [Production of Resin Composition]

### Examples 1 to 6 and Comparative Examples 1 to 4

Each component shown in Table 1 was mixed together with toluene and methyl ethyl ketone in accordance with the blending amount shown in Table 1, stirred and mixed at 25° C. to prepare a varnish-like resin compositions having a solid content concentration of about 60 mass %. In Table 1, the unit of the blending amount of each component is parts by mass, and in the case of a solution, the unit means parts by mass in terms of solid content.

### (Production of Resin Film)

The varnish-like resin composition obtained in each example was applied to a PET film (manufactured by TEIJIN LIMITED., trade name “G2-38”) having a thickness of 38 μm, and then dried by heating at 170° C. for 5 minutes, thereby preparing a resin film in a B-stage state.

[Production of Resin Plate with Double-Sided Copper Foil]

The resin film obtained by the above was peeled off from the PET film, and then pulverized to obtain a resin powder in a B-stage state. A low-profile copper foil (trade name “3EC-VLP-18”, manufactured by MITSUI MINING & SMELTING CO., LTD.) having a thickness of 18 μm was disposed on the upper and lower sides of the Teflon (registered trademark) sheet, that had been die-cut into size of 0.5 mm in thickness, 50 mm in length, and 35 mm in width, into which the resin powder had been introduced. The low-profile copper foil was disposed with the M surface (roughened surface) thereof facing the resin powder side. Subsequently, the laminate before heating and press molding was subjected to heating and press molding under conditions of a temperature of 230° C. and a pressure of 2.0 MPa for a time of 120 minutes, and the resin powder was cured while molding into a resin plate, thereby producing a resin plate with double-sided copper foil. The thickness of the resin plate portion of the obtained resin plate with double-sided copper foil was 0.5 mm.

### (Production of Prepreg)

The varnish-like resin composition obtained by the above was impregnated into an E-glass cloth having a thickness of 0.1 mm, and was dried by heating at 110° C. for 3 minutes to obtain a prepreg having a resin composition content of 48% by mass.

### [Evaluation Methods]

Each evaluation was carried out according to the following methods. The results are shown in Table 1.

### (Measurement Method of Lowest Melt Viscosity and Minimum Melt Viscosity Temperature)

About 0.6 g of resin powder in a B-stage state obtained by grinding the resin film produced in each example was weighed out and formed into a disk-shaped tablet with a diameter of 20 mm using a tablet molding machine. By using this tablet as a measurement sample, the viscosity was measured using a rheometer (trade name “ARES-2K STD-FCO-STD”, manufactured by Rheometric Company) under conditions of a temperature increase rate of 3° C./min, a load of 0.2 N, and a measurement temperature range of 50° C. to 200° C., and the lowest melt viscosity and the lowest melt viscosity temperature were measured. The lowest melt viscosity temperature means a temperature at which the melt viscosity is lowest.

### (Evaluation Method of Non-Adhesion Between Prepregs)

Fifteen prepregs prepared in each example were stacked together and placed in an aluminum deposition pack, which was then compressed at 1 MPa and allowed to stand for one week. After the compression was released, non-adhesion between the prepregs was evaluated according to the following evaluation criteria.
A: The prepregs could be easily peeled off by hand without causing cracks in the prepregs.
B: Cracks occurred in part of the prepreg when the prepregs were peeled off by hand C: The stacked prepregs were integrated with each other and could not be peeled off by hand.

### (Method for Measuring Relative Permittivity (Dk) and Dielectric Dissipation Factor (Df))

The resin plate with double-sided copper foil prepared in each example was immersed in a 10% by mass solution of ammonium persulfate (manufactured by MITSUBISHI GAS CHEMICAL COMPANY, INC.) as a copper etching solution to remove the copper foil. The obtained resin plate was cut into a size of 2 mm×50 mm, and then dried at 105° C. for 1 hour to prepare a test piece. Next, the relative permittivity (Dk) and the dielectric dissipation factor (Df) of the test piece were measured in a 10 GHz band at an atmospheric temperature of 25° C. in accordance with the cavity resonator perturbation method.

### (Flame Retardance)

The resin plate with double-sided copper foil prepared in each example was immersed in a 10% by mass solution of ammonium persulfate (manufactured by MITSUBISHI GAS CHEMICAL COMPANY, INC.) as a copper etching solution to remove the copper foil. The obtained resin plate was cut into a size of 200 mm length×50 mm width to serve as a test piece, and a flammability test was carried out in accordance with the UL standard (UL94VTM).

TABLE 1

| | | | Example | | | | | |
|---|---|---|---|---|---|---|---|---|
| | | | 1 | 2 | 3 | 4 | 5 | 6 |
| Blending | Component | Maleimide resin 1 | 60.0 | 60.0 | 63.8 | 63.8 | 63.8 | 63.8 |
| Composition | (A) | | | | | | | |
| (parts | Component | Maleimide resin 2 | 20.0 | 20.0 | 21.3 | 21.3 | 21.3 | 21.3 |
| by | (A′) | | | | | | | |
| mass) | Component | Phosphate ester compound | 0.5 | 1.0 | 0.5 | 1.0 | 2.0 | 0.5 |
| | (B) | | | | | | | |
| | Component | Modified polyphenylene ether | 10.0 | 10.0 | | | | |
| | (C) | Modified conjugated diene polymer | | | 15.0 | 15.0 | 15.0 | 13.5 |
| | Component | Styrene-based thermoplastic resin | 10.0 | 10.0 | | | | 1.5 |
| | (D) | | | | | | | |
| | Component | Silica | 38.0 | 38.0 | 38.0 | 19.0 | 19.0 | 19.0 |
| | (E) | | | | | | | |
| | Component | Organic peroxide | 2.0 | 2.0 | 2.0 | 2.0 | 2.0 | 2.0 |
| | (F) | Imidazole-based curing accelerator | 0.1 | 0.1 | 0.1 | 0.1 | 0.1 | 0.1 |
| Evaluation | Lowest melt | | 6498 | 6493 | 626 | 566 | 647 | 725 |
| results | viscosity (Pa · s) | | | | | | | |
| | Lowest melt viscosity | | 130 | 132 | 121 | 121 | 122 | 121 |
| | temperature (° C.) | | | | | | | |
| | Non-adhesion | | A | A | A | A | A | A |
| | between prepregs | | | | | | | |
| | Dielectric | Relative permittivity (Dk) | 3.03 | 3.01 | 3.00 | 3.00 | 3.02 | 3.02 |
| | characteristic | Dielectric dissipation factor (Df) | 0.0057 | 0.0061 | 0.0031 | 0.0031 | 0.0031 | 0.0025 |

| | | | | | | |
|---|---|---|---|---|---|---|
| Flame retardance | VTM-0 | VTM-0 | VTM-1 | VTM-0 | VTM-0 | VTM-1 |

| | | | Comparative Example | | | |
|---|---|---|---|---|---|---|
| | | | 1 | 2 | 3 | 4 |
| Blending | Component | Maleimide resin 1 | 60.0 | 63.8 | 60.0 | 60.0 |
| Composition | (A) | | | | | |
| (parts | Component | Maleimide resin 2 | 20.0 | 21.3 | 20.0 | 20.0 |
| by | (A′) | | | | | |
| mass) | Component | Phosphate ester compound | | | | |
| | (B) | | | | | |
| | Component | Modified polyphenylene ether | 10.0 | | 10.0 | |
| | (C) | Modified conjugated diene polymer | | 15.0 | | 10.0 |
| | Component | Styrene-based thermoplastic | 10.0 | | 10.0 | 10.0 |
| | (D) | resin (D) | | | | |
| | Component | Silica | 19.0 | 19.0 | 38.0 | 38.0 |
| | (E) | | | | | |
| | Component | Organic peroxide | 2.0 | 2.0 | 1.0 | 1.0 |
| | (F) | Imidazole-based curing | 0.1 | 0.1 | 0.1 | 0.1 |
| | | accelerator | | | | |
| Evaluation | Lowest melt | | 9281 | 938 | 9340 | 9340 |
| results | viscosity (Pa · s) | | | | | |
| | Lowest melt viscosity | | 130 | 121 | 130 | 130 |
| | temperature (° C.) | | | | | |
| | (Non-adhesion | | A | A | A | C |
| | between prepregs) | | | | | |
| | Dielectric | Relative permittivity (Dk) | 3.03 | 2.99 | 3.03 | 3.03 |
| | characteristic | Dielectric dissipation factor (Df) | 0.0061 | 0.0041 | 0.0061 | 0.0061 |

| | | | | |
|---|---|---|---|---|
| Flame retardance | VTM-1 | VTM-1 | — | — |

*In the table, “—” means not measured.

The details of each component shown in Table 1 are as follows.

### [Component (A)]

Maleimide resin 1: Aromatic bismaleimide resin having an indane ring-containing group represented by the above general formula (A-2): Number-average molecular weight (Mn) 1,300

### [Component (A′)]

Maleimide resin 2: biphenyl aralkyl type maleimide (manufactured by Nippon Kayaku Co., Ltd., trade name “MIR-3000”)

### [Component (B)]

Phosphate ester compound: 4,4′-biphenol-bis(di-2,6-xylenyl phosphate) represented by the following formula (B-6)

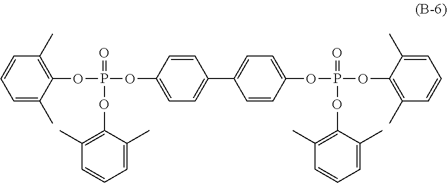 [SMILES: Cc1cccc(C)c1OP(=O)(Oc1ccc(-c2ccc(OP(=O)(Oc3c(C)cccc3C)Oc3c(C)cccc3C)cc2)cc1)Oc1c(C)cccc1C]

### [Component (C)]

Modified polyphenylene ether: Polyphenylene ether having methacryloyl groups at both terminals, weight-average molecular weight (Mw) 1,700
Modified conjugated diene polymer: modified conjugated diene polymer obtained in Production Example 1

### [Component (D)]

Styrene-based thermoplastic resin: styrene-ethylene-butylene-styrene (SEBS) copolymer (product name “KRATON (registered trademark) MD1653” manufactured by Kraton Polymer Japan Inc., melt flow rate: 5.0 g/10 min, styrene content: 30% by mass, hydrogenation rate: 100%)

### [Component (E)]

Silica: Spherical fused silica, average particle diameter (D₅₀): 0.5 μm

### [Component (F)]

Organic peroxide: α,α′-bis(t-butylperoxy)diisopropylbenzene
Imidazole-based curing accelerator: Isocyanate masked imidazole (addition reaction product of hexamethylene diisocyanate resin and 2-ethyl-4-methylimidazole) (trade name “G-8009L” manufactured by DKS Co., Ltd.)

From the results shown in Table 1, when comparing Examples 1 and 2, in which the types of components other than the component (B) are the same, with Comparative Example 1, it can be seen that the resin compositions of Examples 1 and 2 have a lower lowest melt viscosity than the resin composition of Comparative Example 1.

Similarly, when comparing Examples 3 to 5, in which the types of components other than component (B) are the same, with Comparative Example 2, it can be seen that the resin compositions of Examples 3 to 5 have a lower lowest melt viscosity than the resin composition of Comparative Example 2.

### INDUSTRIAL APPLICABILITY

Since the resin composition of the present embodiment has a low lowest melt viscosity while using a maleimide resin as a thermosetting resin, a prepreg, a laminated plate, a printed wiring board, and a semiconductor package using the resin composition, are suitable for applications for electronic components.

1. A resin composition comprising:
(A) one or more selected from the group consisting of maleimide resins having a group containing a fused ring of an aromatic ring and an aliphatic ring and two or more N-substituted maleimide groups, and derivatives of the maleimide resins; and
(B) a phosphate ester compound containing two or more phosphorus atoms, in which the group connecting at least two phosphorus atoms contains two or more aromatic rings.

2. The resin composition according to claim 1,
wherein the group containing a fused ring of an aromatic ring and an aliphatic ring contained in the component (A) is a group containing an indane ring as the fused ring.

3. The resin composition according to claim 2,
wherein the group containing an indane ring is a divalent group represented by the following general formula (A-1), 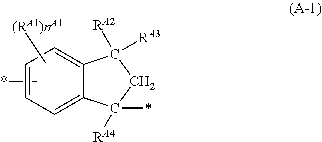
wherein, R^{A1} is an alkyl group having 1 to 10 carbon atoms, an alkyloxy group having 1 to 10 carbon atoms, an alkylthio group having 1 to 10 carbon atoms, an aryl group having 6 to 10 carbon atoms, an aryloxy group having 6 to 10 carbon atoms, an arylthio group having 6 to 10 carbon atoms, a cycloalkyl group having 3 to 10 carbon atoms, a halogen atom, a hydroxy group, or a mercapto group; n^{A1} is an integer of 0 to 3; R^{A2} to R^{A4} are each independently alkyl groups having 1 to 10 carbon atoms; and* denotes a binding site.

4. The resin composition according to claim 1,
wherein the component (B) is a compound represented by the following general formula (B-1), 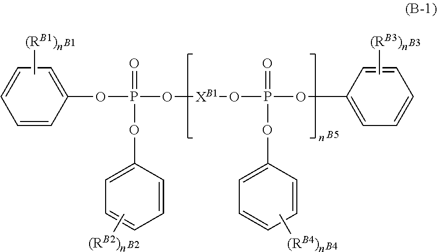
wherein, R^{B1} to R^{B4} are each independently an aliphatic hydrocarbon group having 1 to 5 carbon atoms or a halogen atom; X^{B1} is a divalent group containing two or more aromatic rings; n^{B1} to n^{B4} are each independently an integer of 0 to 5; and n^{B5} is an integer of 1 to 5.

5. The resin composition according to claim 1,
wherein a content of the component (B) is 0.1 to 10 parts by mass with respect to the total amount (100 parts by mass) of the resin components in the resin composition.

6. The resin composition according to claim 1, further comprising:
(C) a compound having two or more functional groups containing an ethylenically unsaturated bond.

7. A prepreg comprising:
the resin composition according to claim 1 or a semi-cured product of the resin composition.

8. A laminated plate comprising:
a cured product of the resin composition according to claim 1; and
a metal foil.

9. A resin film comprising:
the resin composition according to claim 1 or a semi-cured product of the resin composition.

10. A printed wiring board comprising:
a cured product of the resin composition according to claim 1.

11. A semiconductor package comprising: the printed wiring board according to claim 10; and a semiconductor element.
